(19) United States
(12) Patent Application Publication
(10) Pub. No.: US 2020/0066828 A1
(43) Pub. Date: Feb. 27, 2020

(54) FRONT MAINTENANCE APPARATUS FOR FLEXIBLE TILED LED DISPLAY

(71) Applicant: BARCO N.V., Kortrijk (BE)

(72) Inventors: Karim MEERSMAN, Kortemark (BE); Simon Philippe Paul Maria DESNERCK, Deinze (BE); Greet ADAMS, Deerlijk (BE); Floris Albert BONTINCK, Destelbergen (BE)

(73) Assignee: BARCO N.V., Kortrijk (BE)

(21) Appl. No.: 16/466,224

(22) PCT Filed: Dec. 8, 2016
(86) PCT No.: PCT/EP2016/080314

§ 371 Date: Jun. 3, 2019

(30) Foreign Application Priority Data
Dec. 2, 2016 (GB) 1620544.5

(51) Int. Cl. H01L 27/32; G09F 9/302; G09F 9/30; H01L 51/00; H01L 51/52; H01L 51/56

(52) U.S. Cl. CPC H01L 27/3293; G09F 9/3026; G09F 9/301; H01L 2251/568; H01L 51/5237; H01L 51/56; H01L 2251/5338; H01L 51/0097

(57) ABSTRACT

A tiled display that includes a plurality of display tiles including addressable solid state light elements adapted to display at least a part of a static image or video frame on a front side; a support structure for supporting the plurality of display tiles, where in an operation state each display tile has a first shape and where the first and second opposed edges of each of the plurality of display tiles are fixed to the support structure. In a maintenance state at least one of the plurality of display tiles is released from the support structure at at least the first edge and the at least one of the plurality of display tiles then having a second shape modified compared to the first shape and providing an opening between the first edge and the support structure.

The present invention relates to displays comprising display tiles such as display walls as well as methods of manufacturing such tiled displays and display tiles and methods of preparing such tiled displays for maintenance as well as methods of maintaining such tiled displays.

### BACKGROUND There is a need to realize emissive tiled displays of which LED displays are one type and in particular displays that can be maintained and serviced.

Four general approaches can be found in the prior art and that address servicing of LED displays.

A first type of display has front access faces (see FIG. 1A). This is an approach where the entire sign face hinges open to reveal the components. This design has initially appealed to many customers and manufacturers trying to find an innovative solution for service and repair. The main issue is panel door size limitation. Beyond a certain size, the weight of the panel can exert significant loads on the display support structure and this can become a danger to the technician servicing the display. In particular, this can be the case if the display is mounted along a facade of a building several meters or even tens of meters above the ground. Therefore, also the dimensions of each individual panel have a limit, in length and in width.

The second approach has front access doors (see FIG. 1B). This approach is similar to the access face approach, but uses smaller doors over multiple sections of a display. For safety reasons, it is preferred to limit the weight of each section to a few kilograms.

A third approach has Rear Access Doors. This approach cannot be applied easily to displays such as LED displays mounted on the façade of a building or in other applications where access to the back of the display is limited.

The fourth approach has front access panels such as LED Panels. Individual LED modules or panels can be removed from the tiled display to access the components. Examples of front access LED panels can be found in e.g. U.S. Pat. No. 7,055,271 B2 “Electronic display module having a four-point latching system for incorporation into an electronic sign and process”.

When one of the tiles must be removed for inspection, maintenance and/or be replaced, the solution proposed in U.S. Pat. No. 7,055,271 makes use of a tool to trigger a release mechanism. When triggered, the release mechanism allows the tile to be moved outside of the plane of the tiled display either by rotation or translation. This gives direct access to the structure behind the display tile and in particular the fastening means with which the tile is fastened to the support structure of the tiled display. Independently of whether there are two or four bars along which the display tile can slide, or hinges are provided to rotate the tile away from the tiled display; the release mechanism adds to the weight of the display.

A problem with known solutions is that known displays are not compatible with flexible display tiles like the ones disclosed in WO2015063116 “Tiled display and method of assembling same”. The existing solutions also add to the total weight of the display structure which is not desired when the display must be mounted on a structure which might be unable to take that extra load, e.g. on the façade of a building.

There is a need for improvement in the art.

### SUMMARY OF THE INVENTION

A first object of embodiments of the present invention is to provide maintainable tiled displays and display tiles as well as methods of installing and maintaining tiled displays.

A tiled display according to an aspect of the present invention comprises a plurality of display tiles, each display tile having a front side and a back side and at least a first and a second opposing edge and comprising addressable solid state light elements adapted to display at least a part of a static image or video frame on the front side; a support structure for supporting the plurality of display tiles in an operation state or in a maintenance state, wherein in the operation state, each display tile has a first shape and wherein the first and second opposed edges of each of the plurality of display tiles are fixed to the support structure, and in the maintenance state at least one of the plurality of display tiles is released from the support structure at at least the first edge and the at least one of the plurality of display tiles then having a second shape modified compared to said first shape and providing an opening between the first edge and the support structure.

For a tiled display the operative state is the one in which at least a part of a static image or video frame can be displayed on the front side.

An advantage of embodiments of the present invention can be any of, or any combination of:

a) easy access to the back of a display tile of a tiled display, e.g. for maintenance,

b) a lower weight of the installed tiled display

c) the tiled display can be mounted on the façade of a building.

In some embodiments hinges of the prior art techniques are replaced by the ability of the display tiles according to the present invention to change their shape, between a first shape and a second shape, wherein said second shape provides an opening between the first edge and the support structure. Hinges are not excluded from the present invention but any such hinges should preferably not be easily visible from the front side and must not produce a visible seam. The opening between the display tile and the support structure can be further used to perform a maintenance operation such as replacing or repairing a power supply of the tile, a connection box, electronics or even cables. The alteration of shape is not limited to a first flat shape to a second bent shape, but can be the opposite, i.e. first bent shape to a second flat shape or even a bent shape to a more or less bent shape provided in each case a maintenance opening is provided by the change of shape. Accordingly, an importance of the shape alteration is that the second shape provides an opening for maintenance purposes, from the front side.

A hingeless solution reduces the size of the seam between two adjacent tiles which can be nearly in contact with one another. The seam is preferably at most 3 mm, which is indiscernible for a viewer at a distance from the screen and the tiled display appears seamless to the viewer. Hence if a hinge is used it should have a thickness in the operation state of 3 mm or less. Such a hinge can be a of textile or other flexible folded over to produce a flattened V shape with the edges of adjacent tiles being each fixed to one arm of the V shape. Alteranively articulated hinges may be used.

An additional advantage of changing the shape of a tile to perform maintenance operations rather than using a hinge is the reduced number of mechanical parts. This has an impact on the weight and on the cost of the tiled display mechanics but it also simplifies the mounting of the tiled display, and thereby reduces the time required to mount such a display.

In a further aspect of the present invention, each of the plurality of the display tiles comprises a rigid or semi-rigid substrate. Advantages are that rigid and semi-rigid substrates are self-supporting while they have the ability of being bent. Increasing the length of a rigid material results in increasing flexibility.

Using a display tile as a support for the display elements or light elements removes the need of using a frame around each tile. The edges of the tile are preferably made water tight, e.g. by a suitable potting compound.

Further problems of prior art solutions are that the prior art mechanisms are not compatible with display tiles that must be bent, i.e. installed in a bent operative position. The currently existing solutions cannot be used in applications where the tiles will be bent when in operation.

In a further aspect of the present invention, each display tile comprises a flexible display layer comprising the addressable solid state light elements.

Flexible display layers are light weight, can be provided in any size, and as they are flexible they do not alter the rigidity of the display tiles. Additional advantages are that they are easy to install on display tiles.

In a further aspect of the present invention, the rigid or semi-rigid substrate is made of a composite materials such as a metal sandwich material, e.g. an aluminum composite material such as DIBOND® or REYNOBOND®.

Light weight metal composites such aluminum composite materials have many advantages which include a combination of being light weight and rigid simultaneously. As the layers are in aluminum, the material still has elastic properties and can be bent. DIBOND® is an example of such aluminum composite which provides these advantages. It is also suitable for outdoor applications, and increasing the thickness increases the rigidity, and thus more extreme weather conditions can be tolerated, such as strong winds and even earthquakes. Glass fiber or carbon fiber reinforced plastics can also be used.

Another ACM material suitable for the present invention is REYNOBOND®. Advantages of said material are its outdoor resistance.

In a further aspect of the present invention, the rigid or semi-rigid substrate is made of at least one of polyester or a composite panel or a sandwich panel, Polycarbonate, ABS, Polystyrene, PMMA, plastic sheet, aluminum sheet, steel sheet, or metal sheet.

All these materials are also suitable for aspects of the present invention as they are light weight, rigid or semi-rigid, bendable, and easy for procurement.

All these materials have the advantage that they can be bent, and thus a curved display may also be provided.

In a further aspect of the present invention, the first and second edges of each of the plurality of rigid or semi-rigid display tiles can be fixed to the support structure by means of fasteners, the plurality of rigid or semi-rigid display tiles being adapted to be released from the support structure at at least one of the first and second edges via an access point reachable from the front side.

It is an advantage to provide such a fastener to the display tiles as it reduces any step between two adjacent tiles as two adjacent tiles are fixed at a location along their joint edge. Thus, if the wind creates a movement of the tiles, two neighboring tiles will move together, and the tiled display will maintain its seamless appearance.

Such a fastener can advantageously be locked for operation and unlocked for maintenance from the front side, as access to the back is reduced for such a tiled display, e.g. when installed on a solid material such as on the façade of a building. The fasteners according to the present invention are not limited to be accessible from the front side but can also be accessed from the back side, which in certain types of installations is needed, as some installations can only provide back access.

It is therefore an aspect of the present invention, that each display tile can have a third and fourth opposing edge not fixed to the support structure. For a first and a second neighboring tile having the third edge of the first tile and the adjacent fourth edge of the second tile, the first and second tile can be fixed together at at least one location along their third and fourth edges respectively. This fixing can be by a fastener which can be configured to be in a first locked position in an operation state and a second unlocked position in a maintenance state, wherein the change from the first locked position to the second unlocked position and vice versa being activated from the front side.

In another aspect of the present invention, the fastener can be a locking mechanism comprising a first part configured to be attached to the back of the first tile and a second part configured to be attached to the back of the second tile. When installed on the first and second tile, said first and second parts can be arranged so as to face each other and cooperate with one another so as to lock the relative position of the neighboring display tiles in the z direction.

It is a further aspect of the present invention to provide a locking mechanism wherein a first part of the locking mechanism can comprise a rotating body configured to rotate around an axis, the axis being perpendicular to the display tile and an arm that extends away from the rotation axis, the arm and the rotating body forming a single solid body. The second part can comprise a slit arranged so as to be perpendicular to the display tile and configured to receive the arm for fastening the two display tiles with respect to each other in the z direction.

Such a locking mechanism provides the advantage that a card like or knife like tool can be inserted in the seam, between the two neighboring tiles to activate or unlock the locking mechanism. This can be performed from the front of the tiles. This locking mechanism is referred to as a horizontal z-locking mechanism.

It is a further aspect of the present invention that the width of the slit and the thickness of the arm can be configured so that the first and the second tiles fixed by locking mechanism form an angle of preferably at most 20 degrees at their joint edge so as to create a curved tiled display.

By widening the slit, the arm can be inserted inside the slit at different angles, and this tolerance enables two neighboring tiles to form an angle. The inventors have found that a maximal angle of 20 degrees is ideal for such tiled displays. Thus, the fixing mechanisms of the present invention offer the possibility to make curved tiled displays, which are often desired.

It is a further aspect of the present invention to provide a locking mechanism wherein a second part can comprise a first part or section and a second part or section perpendicular to the first part. The first part or section and second part or section of the second part of the locking mechanism can form an L-shape, whereby the second part or section of the second part of the locking mechanism can be parallel to the plane of the second display tile and can be fastened to the second display tile.

It is a further aspect of the present invention, that the first locked position of the locking mechanism can be blocked by the cooperation between a clip having a resilient part and a rounded recess configured to receive a pin, the pin being perpendicular to the display tile and the clip being configured to keep the arm in the slit and maintain the first locked position.

Such a clip has the advantages of ensuring that the locked position remains locked, and even in the presence of wind or vibrations does not open itself.

It is a further aspect of the present invention that the second unlocked position can be blocked by the cooperation between a second clip having a resilient part and a rounded recess configured to receive a pin, the pin being perpendicular to the display tile and the clip being configured to maintain the mechanism unlocked.

Advantageously, such a clip maintains the unlocked position but also blocks the maximal angle of rotation of rotating body and thus of the arm so as to ensure that the arm is in a position for a card-like tool to apply a force on its extremity to lock the mechanism from said unlocked position.

It is a further aspect of the present invention to provide, as an option, further fixation means between an upper tile and a lower tile of the tiled display, the upper tile and the lower tile having a joint edge. The lower part of the upper tile can comprise a lower fixation part along its lower edge. The upper part of the lower tile can comprise a middle mounting bracket along its upper edge configured to cooperate with the lower fixation part so as to fix the upper tile and the lower tile together along their joint edge in the operation state.

Advantageously, the upper part of the lower tile is fixed to the support structure and the by means of the middle mounting bracket which also serves to fix the lower fixation part of the upper tile, and thereby fixes the lower part of the upper tile to the support structure. The middle mounting bracket is hidden by the upper tile, and therefore the upper tile and the lower tile are thereby fixed together, and to the support structure, in a seamless manner.

In a further aspect of the present invention, the lower fixation part and the middle mounting bracket further can comprise alignment means for aligning the first upper tile to the second lower tile.

The alignment means facilitate the installation of a lower tile and an upper tile and also ensure the alignment of the display light elements.

In a further aspect of the present invention, the alignment means can comprise at least one pin provided on the lower fixation part or on the mounting bracket and at least one opening provided on the mounting bracket or the lower fixation part. The pin and the opening can be configured to cooperate so as to align the upper tile and lower tile together in the operation state. Advantageously, such alignment means are easy to manufacture.

In another aspect of the present invention, the lower fixation part or the mounting bracket can comprise at least one magnet for securing the fixation of the lower fixation part and the mounting bracket in the operation state.

The use of magnets provides a further security that the lower fixation part and the middle mounting bracket don't disassemble in the presence of wind for example, vibrations etc.

In a further aspect of the present invention, the part without magnets can comprise for each magnet a cavity configured to receive the magnet so as to align the upper and lower tiles together in the operation state.

In a further aspect of the present invention, at least one opening can be provided on each of the mounting bracket and the lower fixation part for fixing a service rod for use so as to maintain one of the tiles in a bent position in the maintenance state.

The use of a service rod can facilitate the maintenance of the display tile as the user does not have to hold a tile during the maintenance operation. Alternatively, a second user could hold the tile while the first one performs the maintenance.

In a further aspect of the present invention, the lower fixation part further can comprise a lifting bracket which protrudes away from the tile to enable grabbing of the tile with the fingers of a user or with a lifting tool, in which case the lifting bracket further comprises an opening configured to receive said lifting tool, for use in the maintenance state.

Such a lifting bracket is invisible to the viewer and can facilitate the lifting of a tile from the tiled display, as the seam is so small, that it does not allow a finger to grab the edge or the corner of a tile to pull it from the display.

In a further aspect of the present invention an additional fastener can be provided for fixing an upper and a lower tile together at at least one location at the proximity of the joint edge of the upper and lower tile. The fastener can be configured to be in a first locked position for the operation state and a second unlocked position for the maintenance state, wherein the change from the first to the second position and vice versa can be activated from the front side.

Advantageously such a fastener secures the attachment of an upper tile and a lower tile. It can also be accessed from the front side in a similar manner to the horizontal z-locking mechanism provided on the side edges of the tiles.

In a further aspect of the present invention, the fastener can be a locking mechanism, said mechanism being installed on the lower fixation part of the upper tile. The mechanism can comprise a sliding main body and a static second body placed between the sliding main body and the lower fixation part. The sliding main body further can comprise at least one vertical groove parallel to the seam between two neighboring tiles and can be configured to receive a screw and a washer for sliding the screw within the groove. The screw and washer can be configured to be in a first locked position within the groove in the operation state and a second unlocked position within the groove in the maintenance state. The screw can fix further the static second body to the lower fixation part. The main body further can comprise an arm extending from the main body towards the seam between two neighboring tiles. The arm can act as a lever arm upon application of a force at an extremity of the arm. The sliding main body can have a rectangular shape and a length so as to have a surface of overlap with a corner of the middle mounting bracket of the lower tile in the first locked position, so as to block a relative z-movement of the upper and lower tile at this location.

Such a mechanism can be activated with a card-like tool along the seam between two horizontal neighboring tiles. This locking mechanism is referred to as a vertical z-locking mechanism.

In a further aspect of the present invention at least one z-shaped bracket can be provided to be fixed at the back of a display tile, said at least one z-shaped bracket being configured to be inserted in a horizontal z-profile bar forming part of the support structure so as to reduce the flexure of the tile at the location of the z-shaped bracket.

Such brackets are used to reduce the flexure of the tiles for example, and provide a further attachment to the support structure. More than one z-shaped bracket may be used per tile, depending on the length of the tile and if the tile needs to be bended for maintenance.

It is a further aspect of the present invention to provide tiles according to the present invention which can be bent so as to form a curved tiled display. A support structure can be provided with the required matching shape.

As the display tiles are flexible, any shape of tiled display can be made with such a tiled display, from a curved display to a free form, for example for events or concerts.

In a further aspect of the present invention, the support structure can be configured to provide each pair of neighboring tiles at an angle, said angle being of at most 20 degrees.

It is a further aspect of the present invention to provide a method of preparing a tiled display for maintenance, the tiled display comprising, a plurality of display tiles, each display tile having a front side and a back side and at least a first and a second opposing edge and comprising addressable solid state light elements adapted to display at least a part of a static image or video frame on the front side; and a support structure for supporting the plurality of display tiles in an operation state and a maintenance state, the method comprising:
fixing at least one of the plurality of display tiles to the support structure in the operation state by fixing the first and second opposing edges to the support structure whereby the at least one of the plurality of display tiles has a first shape, and
placing at least one of the plurality of display tiles in the maintenance state by releasing at least the first edge of the at least one of the plurality of display tiles from the support structure, whereby the at least one of the plurality of display tiles has a second shape modified compared to said first shape and provides an opening between the first edge and the support structure.

Such a method provides an easy maintenance of a tiled display according to the present invention, allowing front access, a fast and easy way of releasing the first edge of the tile to maintain, this method is also safe for the user as the tiles are lightweight and the risks of accidents are strongly reduced. The tools required for the maintenance operation are also basic tools, such as a card-like tool and a service rod.

### BRIEF DESCRIPTION OF THE FIGURES

FIG. 1A shows an example of front access solution according to the art.

FIG. 1B shows a second example of front access solution according to the art.

FIG. 2A shows a perspective view of a display tile according to the invention.

FIG. 2B. shows a schematic cross section of a display tile according to the invention.

FIG. 3 shows the bending of a tile according to the present invention for front access and maintenance.

FIG. 4 shows the problem of the surfaces of two neighboring tiles being not necessarily flush and the offset delta z between the surfaces of the two neighboring tiles being not constant along their edge, due to the flexibility of the tiles according to the present invention.

FIG. 5 shows a horizontal z-locking mechanism according to the present invention.

FIG. 6A shows the z-locking mechanism in the open position in accordance with an embodiment of the present invention.

FIG. 6B shows the step of locking z-locking mechanism with a card like tool in accordance with an embodiment of the present invention.

FIG. 6C shows the z-locking mechanism in the locked position in accordance with an embodiment of the present invention.

FIG. 7A shows display tiles and their connection box, cables and power supply in accordance with an embodiment of the present invention.

FIG. 7B shows display tiles and their connection box, cables and power supply attached at the back of the tiles in accordance with an embodiment of the present invention.

FIG. 8 shows the front and back side of an upper and lower tile according to an embodiment of the present invention.

FIG. 9 shows a support structure and tiles fixed to the support structure comprising trusses and horizontal z-profile bars according to an embodiment of the present invention.

FIG. 10 shows the back of a tile with a z-shaped bracket according to an embodiment of the present invention.

FIG. 11 shows the fixing of a tile through a termination box to a truss according to an embodiment of the present invention.

FIG. 12 shows a middle mounting bracket provided on the upper part of a lower tile according to an embodiment of the present invention.

FIG. 13 shows a lower fixation part of an upper tile according to an embodiment of the present invention.

FIG. 14 shows the insertion of an upper tile into a lower tile according to an embodiment of the present invention.

FIG. 15A shows a vertical z-locking mechanism in the open position according to an embodiment of the present invention.

FIG. 15B shows a vertical z-locking mechanism during locking according to an embodiment of the present invention.

FIG. 15C shows a vertical z-locking mechanism in the locked position according to an embodiment of the present invention.

FIG. 16 shows the arrangement of upper tiles U and lower tiles L in a tiled display comprising 16 tiles and the location for the front access to the tiles, according to an embodiment of the present invention.

FIG. 17A shows a curved display according to an embodiment of the present invention.

FIG. 17B shows another curved display according to an embodiment of the present invention.

FIG. 18 shows a support structure and tiles fixed to the support structure comprising trusses and horizontal z-profile bars according to an embodiment of the present invention.

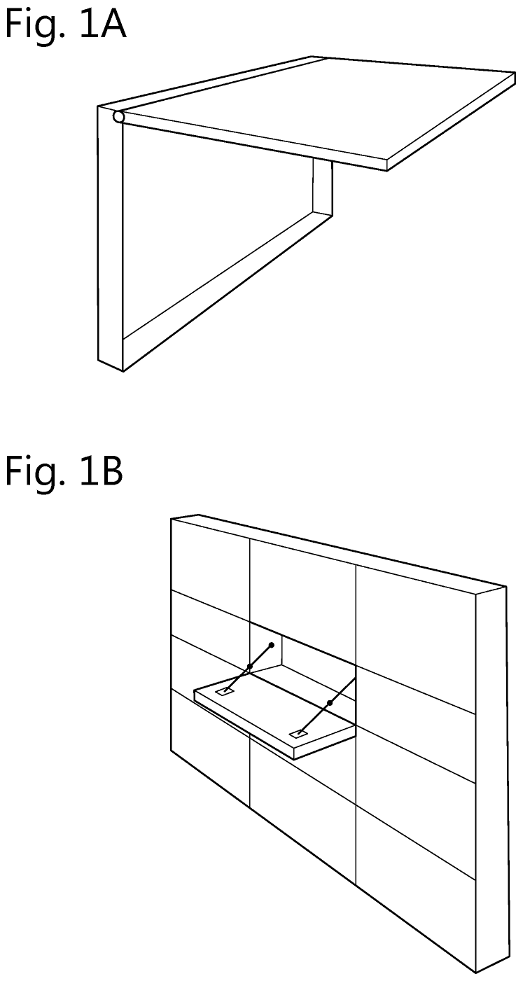

### DEFINITIONS

Clip. A device that holds or hooks. Generally, a clip remains in place because a member of the clip is flexed in the installed position.

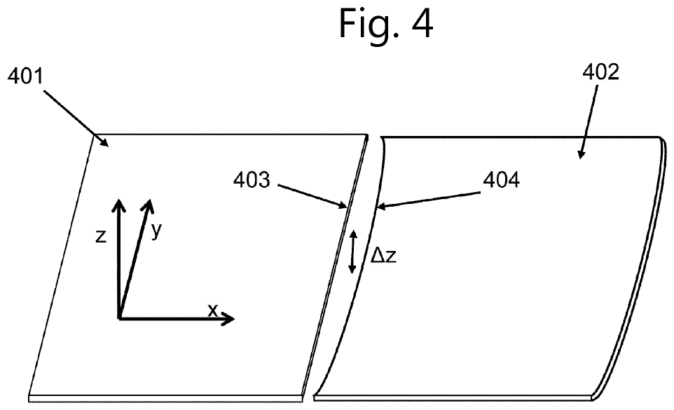

Coordinates X and Y will designate the coordinates of a point in the plane of a tiled display or in a plane parallel to the plane of the tiled display in Cartesian coordinates. Z will designate the coordinate of a point along a direction perpendicular to the plane of the tiled display (see FIG. 4).

Flexural rigidity. For a thin rectangular plate of thickness H, Young's modulus E and Poisson's ratio v; the flexural rigidity is given by:

$$D = \frac{{EH}^{3}}{12 ( 1 - {v}^{2} )}$$

Flush. In the case of a tiled display, two adjacent display tiles are flush when their display surface lie in the same plane.

Nominal. Being according to plan, or as expected.

Light element: light elements according to the present invention can be comprised in at least one of
a construction of a flexible spatial light modulator or light valve, such as a flexible LCD with a backlight, e.g. a backlight having light emitting elements such as flexible printed LED's especially OLEDS,
a construction of a flexible spatial light modulator, such as an LCD illuminated by ambient light, i.e. with no backlight such as electronic paper,
a construction of printed light sources such as LED's especially OLEDS) printed onto a flexible substrate,
a construction of discrete LED light emitting elements fixed to a flexible substrate,
flexible plasma display or any other such imaging constructions.

Rigid plastic. (Definition from Compilation of ASTM Standard Definitions 8th Edition, 1994) For purposes of general classification, a plastic that has a modulus of elasticity, either in flexure or in tension, greater than 700 MPa (100 000 psi) at 23° C. and 50% relative humidity when tested in accordance with Test Method D 747, Test Methods D 790, Test Method D 638, or Test Methods D 882. It is particularly preferred if the modulus of elasticity either in flexure or in tension is between 0.7 GPa and 3.5 GPa when tested in accordance with any of ASTM method D 747, Test for Stiffness of Plastics by means of a cantilever beam, ASTM method D 638, Test for tensile properties of plastics and ASTM methods D 882 test for tensile properties of thin plastic sheeting as given in “Compilation of ASTM Standard Definitions”, Fourth Edition 1979, PCN 03-001079-42, American Society for Testing and Materials, Philadelphia, Pa. 19103, USA.

Semi-rigid plastic. (Definition from Compilation of ASTM Standard Definitions 8th Edition, 1994). For purposes of general classification, a plastic that has a modulus of elasticity, either in flexure or in tension of between 70 and 700 MPa (10 000 and 100 000 psi) at 23° C. and 50% relative humidity when tested in accordance with Test Method D 747, Test Methods D 790, Test Method D 638, or Test Methods D 882.

The above definition of a rigid or semi-rigid plastic material includes the ability of such material to be manipulated elastically into alternative shapes or forms by application of suitable forces such as to be bent as a cantilever beam. A rigid or semi-rigid plastic material is capable of being bent because of its nature of being a plastic material. It is not brittle. It has structural strength so that it is self-supporting and less likely to form wrinkles or bulges when bent. Plastic sheets act as beams when subjected to externally applied transverse loads and deflect and change shape accordingly. The magnitude of any change in shape will depend upon:
1. the length of the beam—in embodiments of the present invention greater than 1 meter
2. the external bending moment—as required to adapt the screen to the curved frame and held by the distributed fastening means
3. the shape and size of the beam cross-section—in embodiments of the present invention the shape of a sheet of plastic
4. the modulus of elasticity of the beam material—as defined above for a rigid plastic material.

Any material used in a tiled display should preferably be temperature resistant, e.g. able to maintain physical integrity at 60° C. The substrate material has to be transparent when used for rear-projection and is then preferably covered with a thin translucent white layer on the side away from the projectors to display the projected image on the side towards the viewers.

A suitable material for the display screen is polycarbonate. Also, PMMA can be used. The thickness can be from 2.5 to 3.5 mm. It has been found that for PMMA or polycarbonate 2 mm is too floppy, 4 mm is too rigid. A suitable E-modulus for the material lies between 0.8 and 4 GPa, particularly between 1.5 and 3.5 GPa (E-mod of polycarbonate for example 2-2.4 GPa and E-mod of PMMA for example 1.8-3.1). A typical size is 1.4×7 up to 10 m width and 3 m height, whereas lower dimensions of a full screen could be 1.8 by 1 meters. Generally, one dimension will be greater than 1 meter.

Joint edge. A joint edge represents the edge between two neighboring display tiles wherein the tiles are in contact with each other along the edge or are almost in contact as they are being separated by a seam.

### DESCRIPTION OF EXAMPLE OF ILLUSTRATIVE EMBODIMENTS

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes. Where the term “comprising” is used in the present description and claims, it does not exclude other elements or steps. Furthermore, the terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

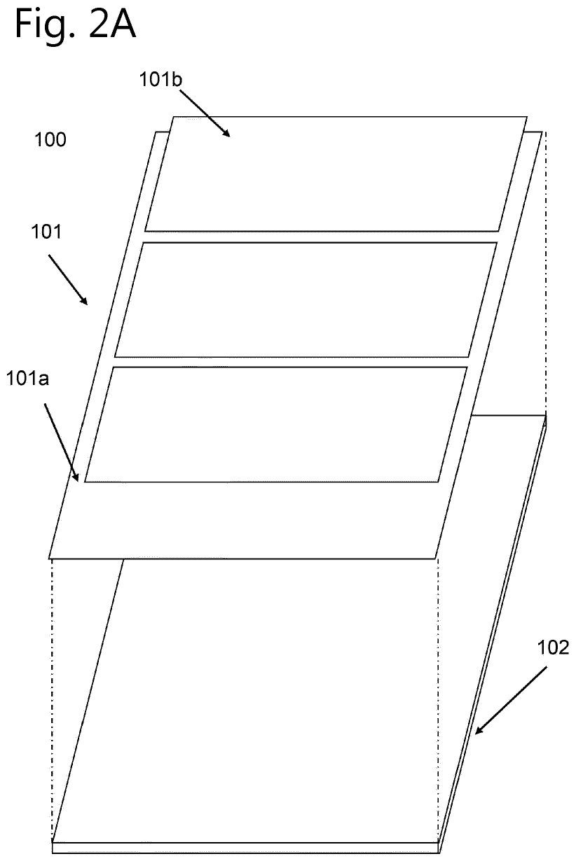

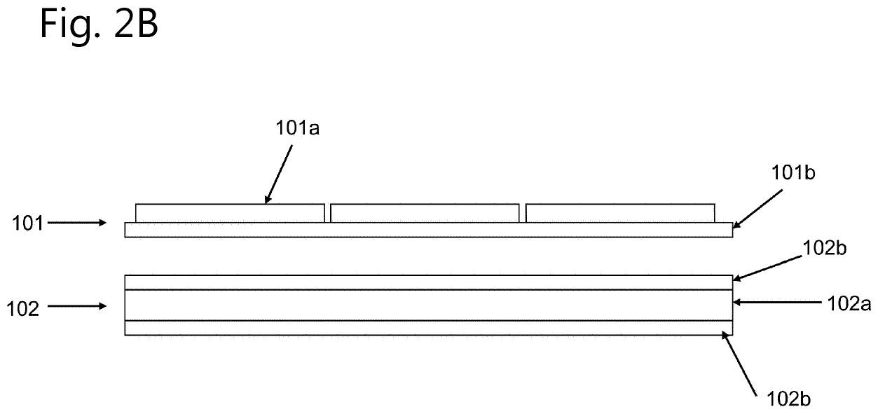

FIG. 2A shows a perspective view of a display tile 100 according to an embodiment of the present invention. A flexible display 101 is fastened to a rigid or semi-rigid substrate 102. An example of flexible display 101 is given in patent application laid-open WO02015063115 “Flexible display tile and method of producing same” and US20160267836 “Tiled display and method of assembling same”. The flexible display 101 has a flexible substrate 101a on which electrically conductive tracks are formed (not shown on FIG. 2A). Display tiles 101b (on which Light Emitting Diodes are mounted) are fastened to the flexible substrate 101a and electrical connections are established between the conductive tracks on the flexible substrate 101a and drive electronics on the display tiles 101b. The flexible display 101 may not be able to support its own weight. From a mechanical point of view, the flexible display 101 can behave like a canvas or a sheet of rubber. In this embodiment, the display tiles are flat in the operative state.

An additional advantage of the flexible display 101 is described in the patent application WO2015063115 page 18 line 27 to 34: “Accordingly, the display tile is configured in such a way that it can be cut along a line passing between two columns of enclosure elements and/or along a line passing between two rows of enclosure elements, each enclosure delimiting a potted island on the tile. This has the advantage that the dimensions of a tile can easily be modified to realize a tiled display of a desired length and width that would otherwise require a tailor-made tile” wherein the display tile refers to the flexible display and the enclosure elements is an element comprising LEDs, for example two. Thus, the dimensions of the semi-rigid substrate and of the flexible display can be adapted to the desired application.

The rigid or semi-rigid substrate 102 can be a composite material such as a metal composite material of which an aluminum composite material is one example comprising two aluminum plates 102b separated by a core having one or more layers of plastic material such as a polyethylene core 102a as seen on FIG. 2B. An example of suitable aluminum composite material is DIBOND® made by 3A Composites (formerly known as Alcan Composites). Each aluminum plate is fastened to the polyethylene core (e.g. by gluing). The dimensions of the composite substrate are for instance more than 250 mm on any edge, e.g. 260 mm×1170 mm. The aluminum plates have a thickness of 0.2 to 3 mm e.g. 0.3 mm each. The polyethylene core has a thickness of 1 to 6 mm e.g. 1.4 mm to 5.4 mm. The thickness of the polyethylene core is chosen in function of the width and length of the composite substrate as will be discussed later. For the sake of clarity, a flexible display tile 100 is to be understood such that the flexural rigidity of the display tile is essentially determined by the composite substrate. This does not exclude from the scope of the invention flexible displays 101 and substrates 102 whose combined flexural rigidity would be the same as the flexural rigidity of the substrate 102 described in the example of embodiments.

The rigid or semi-rigid substrate 102 may also be a sandwich panel, which is a structure made of three layers. It can comprise a low-density core between two outer layers. Advantages of such panels are the excellent mechanical performance achieved for a minimal weight, as for example a high rigidity, as the core of such a panel absorbs the shear stresses and the layers absorb the in-plane stresses, i.e. tension and compression. For ACM materials, the layers are made of aluminum and thus are elastic materials. Thus, the elasticity of such a plate is dominated by the elasticity of the metallic layers, and thus such a material can be bent elastically. Thus, the advantage of a light weight material, rigid and elastic are all simultaneously achieved with ACM materials.

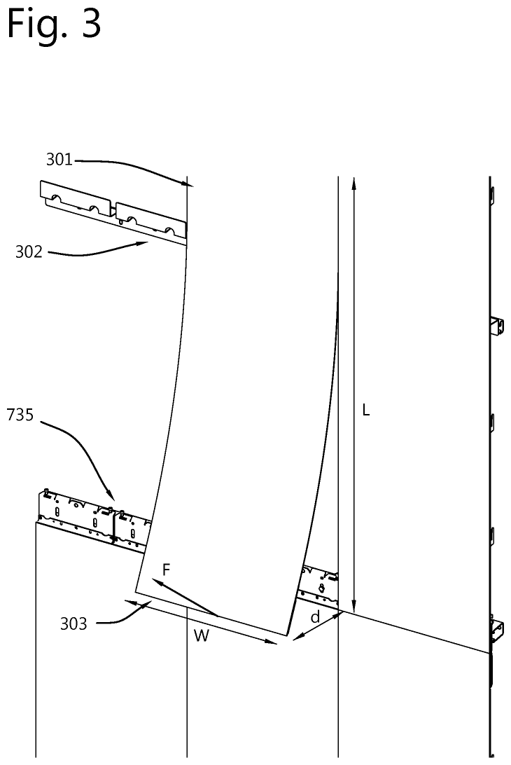

When bent the structural behavior of a display tile according to embodiments of the present invention can be described by a mechanical model, e.g. that of a cantilever beam. As described further below, the tiles, assuming they have a rectangular shape (although the invention is not limited thereto), can be fixed to the support structure at their extremities, e.g. along edges. Such a display tile preferably has a shape that allows tessellation. Tessellation of a flat surface is the tiling of a plane using one or more geometric shapes, called tiles, with no overlaps and substantially no gaps. The individual tiles do not need to have the same shape (although this may be preferred). So different shapes may be combined together. A convenient shape is that of a rectangle whereby the opposed shorter edges of the rectangle can be fixed to the support. During maintenance operations, one of the shorter edges is released and thus the tile is only fixed at one end like a cantilever beam. For maintenance operations, as described below and further shown on FIG. 3, the free end is pulled away from the first position by a user and thereby forming an opening for maintenance. The tile can be propped open. The tile in this maintenance state is a flexed cantilever beam, preferably an elastically flexed cantilever beam.

The rectangular shape can have a 4:3 (4 units width 3 units high) or 16:9 aspect ratio for example. However, a preferred format for display tiles is also a square.

Advantageously, the material of the rigid or semi-rigid substrate 102 has a coefficient of thermal expansion which is similar to the coefficient of thermal expansion of the flexible display 101. Such an advantage is provided with composite materials such as DIBOND®, as the coefficient of thermal expansion of DIBOND® is approximately 24×10⁻⁶ m/(m K). and of the coefficient of thermal expansion of the flexible display is approximately 18×10⁻⁶ m/(m K).

However, if the flexible tiled display is to be installed in an environment where temperature variations are negligible, i.e. where the temperature is controlled, such as in an indoor cinema for example, small temperature variations are expected and other materials for the rigid or semi-rigid substrate could also be used.

Other suitable materials for the semi-rigid substrate than DIBOND® are the following:
other composite materials such as other ACMs, for example REYNOBOND®, polyester or more general composite panels or sandwich panels, fiber reinforced plastics
Polycarbonate, ABS, Polystyrene, PMMA, or more general: plastic sheets
a light metal sheet such as an aluminum sheet, steel sheet, or more general: sheet metal sheets

The flexural rigidity of the display tile 100 is preferably chosen so that (1) a human operator can easily bend the display tile, (2) the tile, when bent, adopts a shape that allows easy access to the electronics and mechanics at the back of the tiled display and (3) the tile is rigid enough not to flap uncontrollably in windy conditions typical of those found along the facades of buildings on which the tiled display is installed.

The following table shows the structural characteristics of DIBOND® for various panel thicknesses. The thickness of each aluminum layer 102b remains of 0.3 mm, whereas the thickness of the entire panel varies from 2 mm to 6 mm, thus 1.4 mm to 5.4 mm for the core.

| Panel thickness | 2 mm | 3 mm | 4 mm | 6 mm |
|---|---|---|---|---|
| thickness of aluminum layer | 0.3 mm | | | |
| weight [kg/m²] | 2.90 | 3.80 | 4.75 | 6.60 |
| technical properties | | | | |
| Section Modulus W | 0.51 | 0.81 | 1.11 | 1.71 |
| Rigidity (Poisson's ratio | 345 | 865 | 1620 | 3840 |
| μ = 0.3) E.I [kN cm²/m] | | | | |

| | |
|---|---|
| Modulus of Elaticity [N/mm²] | 70 000 |
| Tensile Strength of | Rₘ 145-185 |
| Aluminum [N/mm²] | |
| Proof Stress (0.2%) [N/mm²] | R_{p0.2} 110-175 |
| Elongation [%] | A50 ≥ 35 |
| Linear Thermal Expansion | 2.4 mm/m at 100° C. temperature |
| | difference |
| Core | |
| Polyethylene, Typ LDPE | 0.92 |
| [g/cm³] | |

Additional advantages of using a flexible tiled display according to embodiments of the present invention are that the weight of the display tiles is significantly decreased with respect to known rigid display tiles. As an example, the weight of the flexible display can be 6.3 kg/m² and the weight of DIBOND® is of 5.5 kg/m². The total weight, which includes the brackets used for attaching the tiled display is 13 kg/m². The weight is reduced with respect to prior art tiled displays by approximately a factor of two. The total weight, which includes the brackets used for attaching the tiled display is preferably less than 50 kg/m², e.g. less than 30 kg/m², or less than 20 kg/m².

REYNOBOND® is another type of ACM, mostly used in outdoor applications because of its resistance to bad weather and UV radiation. Therefore, REYNOBOND® is also suitable for the present invention.

FIG. 3 shows a display tile 100 according to an example of embodiment of this invention in a flat operative state and in a bent preferably elastically bent maintenance state. While one of the extremities of the display tile is fastened to the support structure of the tiled display and the other extremity is free, a human operator can elastically bend the display tile 100 into a position wherein the bottom edge 303 is away from the underlying support 302, the tile being bent like a cantilevered beam. For example, by applying a force between 5 N and 100 N at the bottom free extremity (edge 303) of the display tile, the deflection is enough to achieve access to the back of the tiled display. When a force of 5 to 100 N is applied to an edge of the display tile it is preferred if this produces an opening of 20 to 50 cm between the edge and the support structure. Preferably application of the force results in any part of the display tile having an angle of less than 30 degrees with the normal to the plate in its rest position.

Such a force applied to the edge of the display tile can preferably apply a torque of 2.5 Nm to 30 Nm (Force X length of tile) with an opening of 20 to 50 cm”.

FIG. 3 shows a perspective view of a tiled display with display tile 100 bent so that at one extremity the edge of the display tile is separated from the underlying support. As shown in FIG. 3, the tile 100 is part of a tiled display. A first extremity or edge 301 of the display tile is fastened to the support structure (like e.g. the support structure may include a truss 302 that is fastened to a wall). A force F is applied to a second extremity e.g. edge 303 of the tile. The force F has a component Fₙ normal to the surface of the tile. For a tile made out of a material similar to a DIBOND® substrate that is 260 mm wide and 1200 mm long, a deflection d of several centimeters to several tens of centimeters is possible with Fₙ varying from 10 N to 100 N or more.

The flexural rigidity of the composite substrate may vary from e.g. 100 to 4000 kNcm²/m, typically 100 to 2000 kNcm²/m. Flexural rigidity increases as a power of the thickness of a plate. Therefore, the thickness and length will be chosen as a function of the environment wherein the tiled display is to be installed. In particular, environmental loadings such as wind conditions or snow or ice loadings, as well as other environmental characteristics such as minimum and maximum temperatures are preferably taken into account. Also, if the tiled display is to be installed on a skyscraper for example, as wind speed increases with altitude, the thickness of the tiled displays may need to be adapted, while still being flexible enough to enable bending of the tile as illustrated on FIG. 3 to enable front access and therefore for maintenance. Therefore, the length of the tile, the thickness of the tile, the materials used and environmental factors such as wind loadings will preferably all have to be taken into account when designing the tile so as to allow front access maintenance by bending of the tile but also have a tile which is rigid enough for any weather conditions, or even earthquakes.

The inventors have found that the following dimensions satisfy those requirements for most indoor or outdoor applications: the thickness is preferably in the range of 2 to 4 mm for plates that are up to approximately 2-meter long. Thicker plates are also possible for longer tiles e.g. from 2 m to 4 m long or even longer.

The maximal dimensions of a tile according to embodiments of the present invention are preferably 600 mm in width and 5000 mm in length.

In embodiments of the present invention, the display tiles described above are arranged in a tiled display, comprising a plurality of display tiles, each display tile having a front side and a back side and at least a first and a second opposing edge (e.g. edges 301 and 303 in FIG. 3) and comprising addressable solid state light elements adapted to display at least a part of a static image or video frame on the front side. The light elements can be emissive or transmissive light elements. A support structure is provided (e.g. 302 of FIG. 3) for supporting the plurality of display tiles in an operation state and a maintenance state, wherein in the operation state, each display tile has a first shape and wherein the first and second edges of each of the plurality of display tiles are fixed to the support structure, and in the maintenance state at least one of the plurality of display tiles is released from the support structure at at least the first edge and the at least one of the plurality of display tiles has a second shape modified compared to said first shape and providing an opening between the first edge and the support structure. The display tiles preferably do not require a hinge to allow movement of the tile from the operative to the maintenance states. Hence the tiles when mounted are preferably fixed to the support in a hingeless manner.

The first and second opposed edges of each of the plurality of semi-rigid display tiles can be fixed to the support structure by means of fasteners in accordance with embodiments of the present invention. The plurality of semi-rigid display tiles is preferably adapted to be released from the support structure at at least one of the first and second edges via an access point reachable from the front side.

Embodiments of the present invention include a tiled display with a seamless appearance thanks to the types of fixations of the tiles to the support structure, i.e. there is no visible frame for the display tiles due to the semi-rigid substrate and there is preferably no hinge for allowing a front access to the tiles from the front. Advantageously, the seam is reduced to a maximum of 5 mm e.g. 1 mm to 3 mm, and even less (0.5 mm). Therefore, to enable front access to the tiles, a tool such as a card-like tool can be inserted in the seam between two neighboring tiles (in the horizontal direction or in the vertical direction). Thus, the tool or card-like tool preferably has a thickness of at most 2.5 mm, preferably 0.5 to 2 mm depending on the dimensions of the seam. Note that a credit card has a thickness of 0.76 mm and is suitable for the present invention.

In a preferred embodiment of the present invention, no hinges are used for enabling a front access to the tiles. The insertion of a hinge at for example one edge of a tile increases the seam as the seam has to have the dimensions of the thickness of a tile to enable the opening. However, a hinge comprising a translation mechanism could be used in order to have a front access with a hinge while maintaining a reduced seam and a seamless appearance to a user.

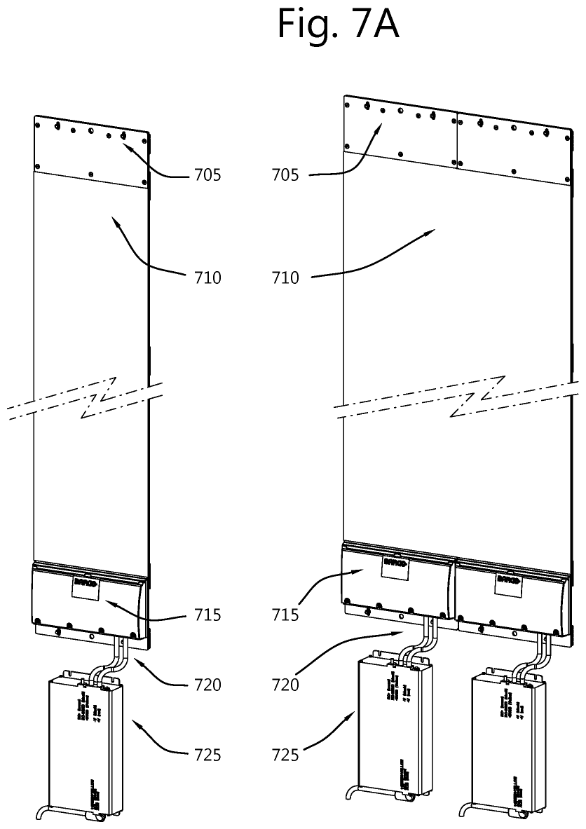

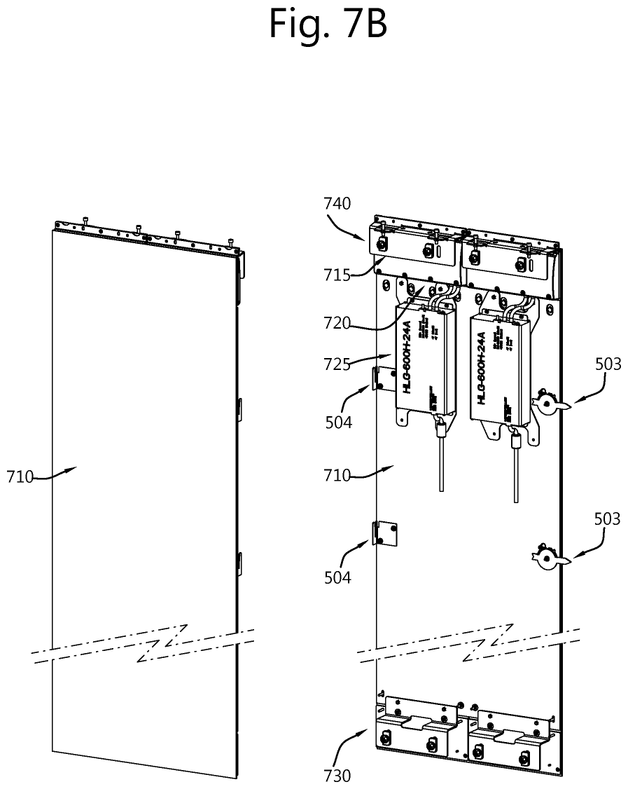

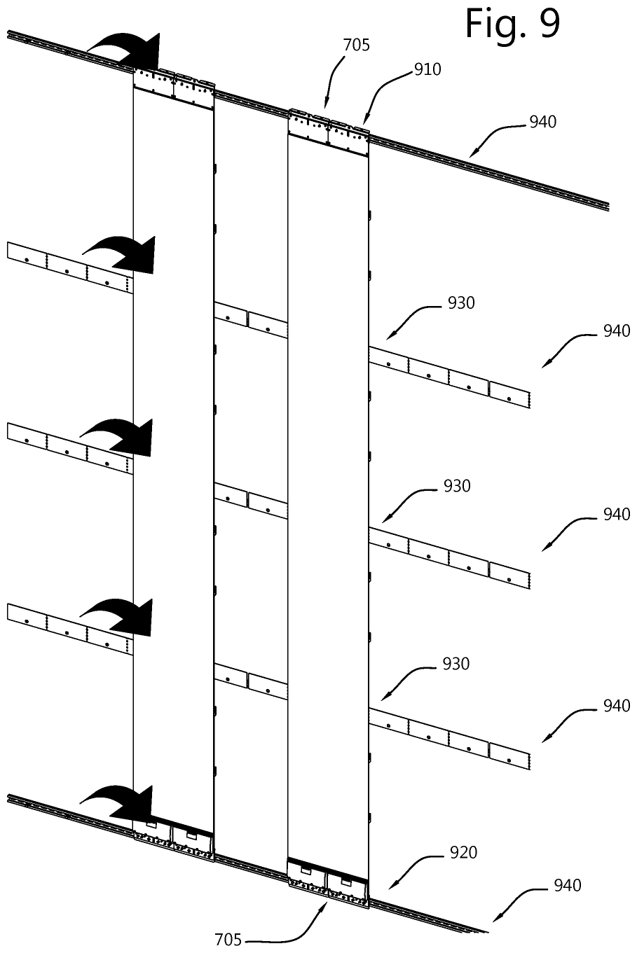

In an embodiment according to the present invention shown in FIG. 7A, a plurality of display tiles 710 can be mounted on a wall by placing the tiles next to each other in the horizontal direction with a seamless appearance. In this embodiment, a connection box 715 comprising electronics, cables 720 and a power supply 725 can be placed for example underneath each display tile 710, as illustrated in FIG. 7A. A termination box 705 can serve as an interface to attach each display tile to a support structure. In another embodiment, the connection box 715, the cables 720 and the power supply 725 can be attached to the back of the display tile, as illustrated in FIG. 7B. In this embodiment, the distance between the wall and the display tile is increased. When the display tiles are positioned next to each other, the display tiles are preferably attached at both extremities to a support structure by means of brackets, respectively bracket 740 for the upper extremity and bracket 730 for the lower extremity. The support structure can comprise for example a plurality of truss 940 such as Unistrust® bars whose positioning is adapted to the dimensions and brackets of the display tiles as shown in FIG. 9. In this embodiment, the upper 910 and lower extremity 920 of the display tiles, or the first and second edges of the display tiles, are fixed to the support structure, i.e. to the bars 940 by means of nuts and bolts, via brackets of the type 730 and 740, as illustrated on FIG. 7B.

FIG. 9 shows a support structure comprising trusses 940 such as Unistrust® bars and two display tiles according to the present invention being installed on the support structure. In this embodiment, the display tiles are fixed to the support structure 940 at their upper 910 and lower 920 extremity by means of termination box 705.

FIG. 11 shows an embodiment of the present invention showing how to fix the termination box 705 in the upper part of a tile 710 to the support structure, i.e. a truss such as a Unistrust® bar 940 with nuts and bolts.

However, the display tiles being flexible, the surfaces of two neighboring tiles are not necessarily flush (as illustrated on FIG. 4). The offset delta z between the surfaces of neighboring tiles 401 and 402 is not necessarily constant along the edges 403 and 404. There may be multiple causes for this, e.g. different wind loads on different parts of the tiled display, stress applied at the extremities of one or more tiles can slightly bend the tile out of the nominal plane of the display surface. A first drawback is that the tiled display does not appear seamless to the viewer.

Therefore, in order to reduce the seam between neighboring tiles, in a preferred embodiment of the present invention, the display tiles have a third and fourth opposing edge not fixed to the support structure and wherein for a first 501 and a second 502 neighboring tile along the third edge 403 of the first tile and the fourth edge 404 of the second tile, said edge being a joint edge, the first and second tile are fixed together at at least one location along their third and fourth edges respectively by a fastener which is configured to be in a first locked position in an operation state and a second unlocked position in a maintenance state, wherein the change from the first locked position to the second unlocked position and vice versa being activated from the front side.

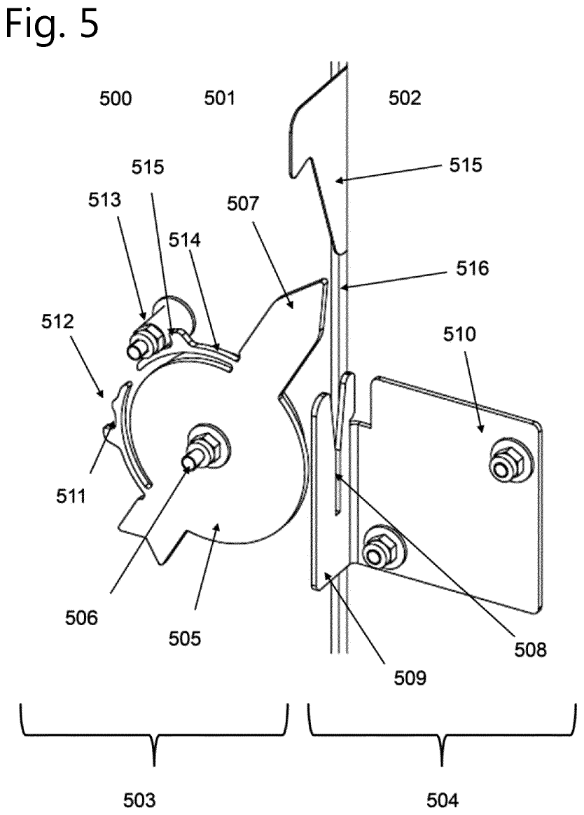

An embodiment of such a locking mechanism 500 is illustrated on FIG. 5. The locking mechanism 500 limits the amplitude of the offset delta z that can exist between two neighboring display tiles like 401 and 402 shown on FIG. 4, and thereby reduces the seam between neighboring display tiles which would disturb the viewer.

The mechanism comprises a first part 503 and a second part 504. The first part 503 is fastened to the first 501 of the two neighboring display tiles. The second part 504 is fastened to the second 502 of the two neighboring display tiles. When the display tiles 501 and 502 are fastened to the support structure of the tiled display, the first part 503 and the second part 504 are fixed to each tile so as to face each other and collaborate with one another.

In a preferred embodiment according to the present invention, the first part 503 and the second part 504 can interact to lock the relative position of the neighboring display tiles 501 and 502 in the z direction thereby contributing to a flush display surface across the tiled display.

The first part 503 of the locking mechanism comprises a rotating body 505. The rotating body 505 can rotate around an axis 506. The axis 506 is perpendicular to the display tile 501.

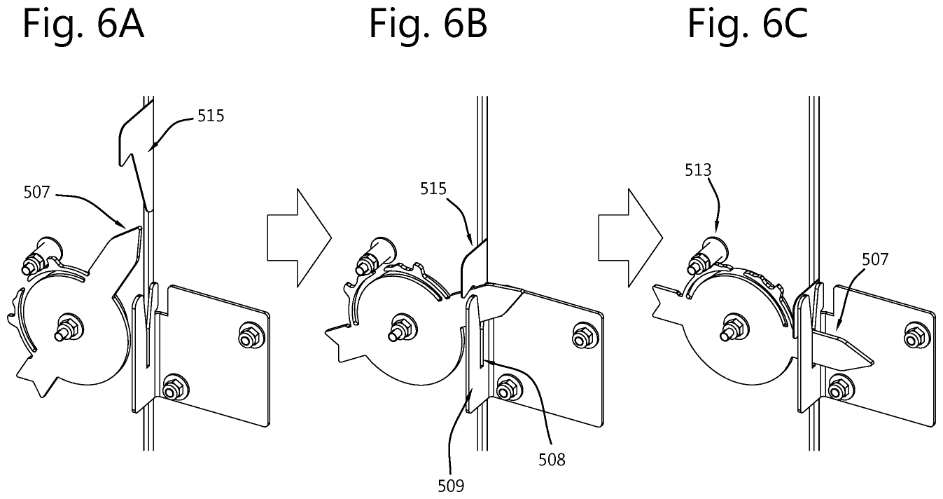

The rotating body has an arm 507 that extends away from the rotation axis 506. The arm 507 and the rotating body form a single solid body (i.e. the relative positions of the rotating body 505 and the arm 507 are fixed). By rotating the rotating body 505, the arm 507 can enter or exit a slit 508 in a first part 509 of the second part 503 of the locking mechanism 500, depending on the rotation direction and the previous position. The rotating body 505 and arm 507 have at least one first stable position. The first stable position corresponds to the locked position wherein the arm 507 is fully engaged into the slit 508 in the first part 509 of the second part 503 of the locking mechanism, as illustrated on FIG. 6C, and in which the display tiles are fixed with respect to each other in the z direction. The first part 509 is perpendicular to a second part 510 of the second part 503 of the locking mechanism. The first part 509 and second part 510 of the second part 503 of the locking mechanism form a L-shape. The second part 510 of the second part 503 of the locking mechanism is parallel to the plane of the second display tile 502 and fastened to the second display tile 502 (e.g. by means of screws through an aluminum plate of the aluminum composite material used as substrate).

The stability of the first stable position, the locked position, is assured by a clip 512. The clip 512 has a rounded recess 511 that can hook a pin 513. The pin 513 is perpendicular to the display tile 501. The clip 512 holds the arm 507 in the slit 508 and keeps the mechanism locked until the mechanism is unlocked by an operator. Once the clip 512 clasps the pin 513, the rotating body 505 and arm 507 cannot be rotated further. On the other hand, by applying a sufficiently high torque to the rotating body (e.g. by applying a force on the arm 507), it is possible to release the clip 512 and rotate the rotating body 505 and the arm 507 in order to take the arm 507 out of the slit 508 and unlock the mechanism. The rotating body 505 and arm 507 can have a second stable position. The second stable position corresponds to the unlocked position when the arm 507 is outside of the slit 508 in the first part 509 of the second part 503 of the locking mechanism, as illustrated on FIG. 6A. The stability, or the maximal angle of rotation of the second stable position can be assured by a second clip 514. Both clips 512 and 514 have a resilient part. The resilient part facilitates the engagement and disengagement of the pin 513 into the recess (e.g. 511 in clip 512 and 515 in clip 514).

The rotating body 505 and the arm 507 can be rotated by applying a force on the arm 507, which acts as a lever arm. The force can be applied by a card-like tool 515 that is slid through the seam 516 that exists between the neighboring display tiles 501 and 502. This is illustrated on FIGS. 6A, 6B and 6C.

The maximal angle of rotation in each closed and open position, as illustrated on FIGS. 6C and 6A respectively, is thus ensured by the cooperation of the clips 512 and 514 respectively and the pin 513. In the open position, the clip 514 and the arm 507 are such that the arm 507 extends across the seam 516 such that the insertion of the card-like tool 515, can enter into contact with the upper extremity of the arm 507, as shown on FIG. 6A, and by sliding the card-like tool downwards as illustrated on FIG. 6B, a force is applied on the arm 507 acting as a lever, which thereby causes a clockwise rotation of the rotating body 505 until it reaches the first stable position, the lock position shown in FIG. 6C. The opposite sequence is performed for unlocking the z-lock mechanism. The card-like tool can be inserted under the arm 507 and slid upwards so as to apply a force on the arm acting as a lever arm which thereby causes a counter-clockwise rotation of the rotating body until it reaches the second stable position, the un-locked position, as shown in FIG. 6A. This sequence is not shown in the Figures.

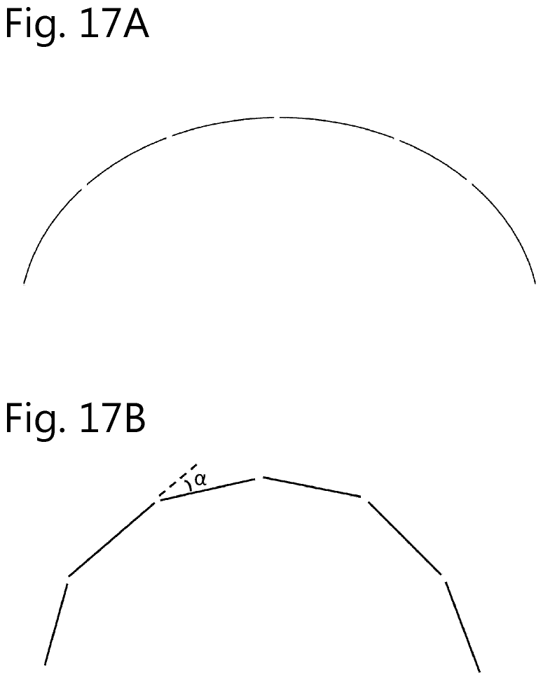

The length of the arm 507, the dimensioning of the slit 508, in particular its width, and the thickness of the arm 507 are chosen such that two neighboring tiles fixed by the horizontal z-locking mechanism form an angle of preferably at most 20 degrees at their joint edge so as to create a curved tiled display, as shown on FIG. 17B. At the joint edge between two neighboring tiles, there is thus no abrupt change in the z-direction, such as a step.

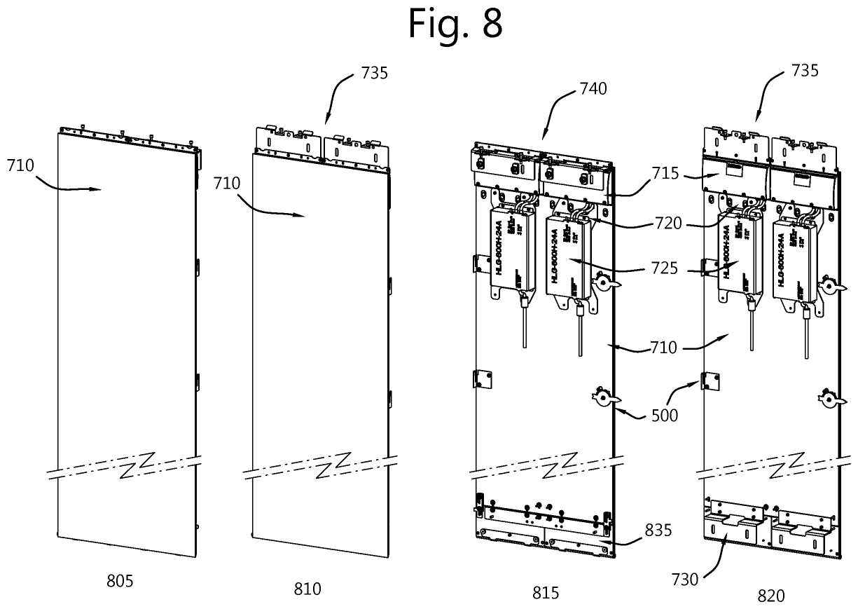

In another embodiment according to the present invention, the display tiles can be stacked, i.e. placed next to each other in the vertical direction. In this embodiment, to enable a seamless appearance, the extremities of the display tiles are fixed differently than in the previous embodiment wherein the display tiles are placed next to each other horizontally. The upper fixation 735 of a lower tile and the lower fixation 835 of an upper tile to the support structure is arranged so as not to show a seam nor the fixations. FIG. 8 illustrates the front 805, 815 and back sides 810, 820 of an upper and lower tile according to this embodiment. As shown on FIG. 3, the bottom part of the upper tile is fixed to the upper part of the lower tile, which is first installed to the structure.

Note that the present description of the upper tile and lower tile, but also of neighboring tiles also applies if the tiled display is rotated by 90°, i.e. the upper tile would become the left or right tile and the lower tile would become the right or left tile.

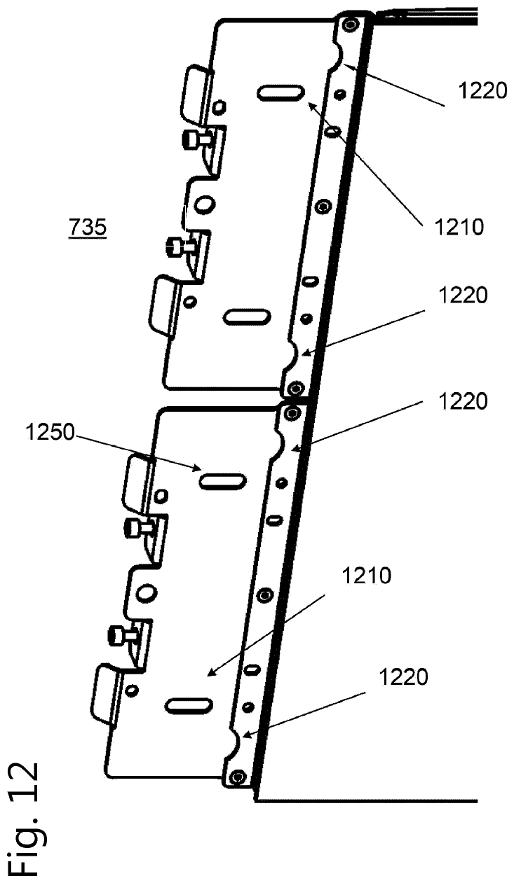

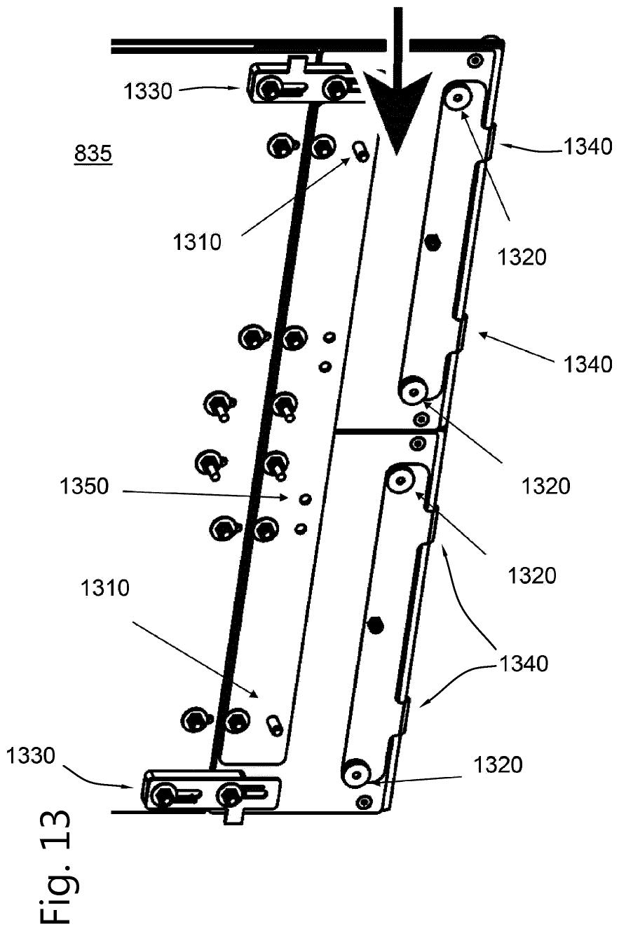

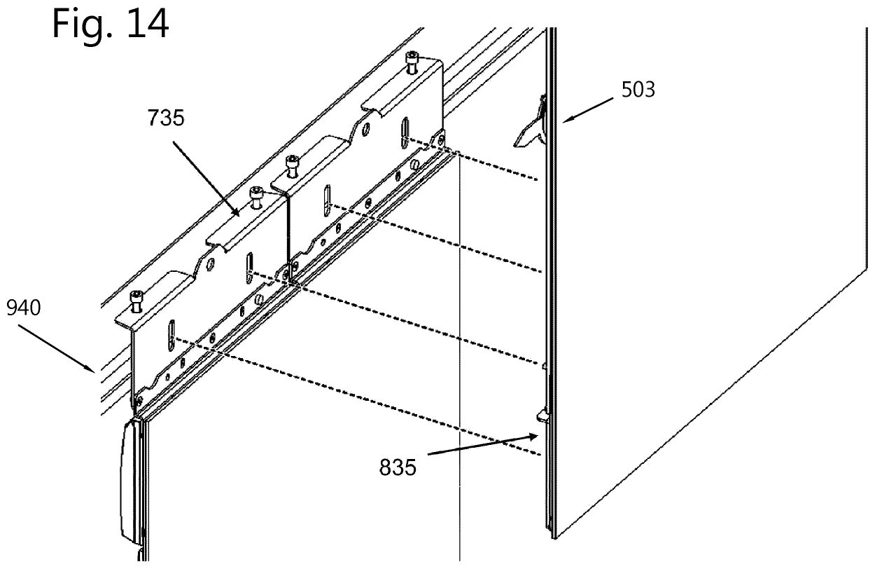

FIG. 12 shows a front view of a middle mounting bracket 735 (or upper fixation) used to fix the upper part of a lower tile to the support structure. Note the middle mounting bracket 735 can be similar to the termination box 705. FIG. 13 shows the lower fixation part 835 of an upper tile. These two parts are configured to cooperate with one another so as to fix the tiles together while ensuring a perfect alignment between the tiles. Alignment means can be incorporated in the middle mounting bracket 735 or in the lower fixation part 835. In a preferred embodiment, the alignment means comprise a pin 1310 provided for example on the lower fixation part 835 of the higher tile, and which is configured to cooperate with an opening 1210, provided for example on the middle mounting bracket 735. The cooperation of the two is schematically shown on FIG. 14. However, as the upper tile is preferably first fixed in the upper part, as explained below, when it is being fixed to the middle mounting bracket, the step of fixing the lower part of the upper tile requires a bending of the tile as shown on FIG. 3. The bending is not shown on FIG. 14.

In an embodiment according to the present invention, in order to secure the fixation between an upper and lower tile, at least one magnet is provided either on the middle mounting bracket 735 or on the lower fixation part 835. FIG. 13 shows four magnets 1320 placed on the lower fixation part 835. On FIG. 12, four cavities 1220 to receive the magnets 1320 are provided so as to further act as alignment means between the two tiles. The middle mounting bracket is in this embodiment made of a magnetic material. Thus, the magnets act as alignment means and as additional fastening means for securing the fixation between an upper and a lower tile.

In a preferred embodiment, the lower fixation part 835 and the middle mounting bracket 735 further comprise an opening for installing a service rod during maintenance, to maintain for example the upper tile in a bended or curved position. The openings are shown in FIGS. 12 and 13 with reference numbers 1250 and 1350 respectively. If it is the lower tile which requires maintenance, the upper tile first has to be lifted, then the user has access to the lower tile and may remove the nuts and bolts attaching the lower tile to the middle mounting bracket 735. The lower tile can then be bent towards the user, and the user can perform maintenance operations on said tile. The dimensions of tiles, the middle mounting bracket and the lower fixation part are such that there is enough space for the bending of the upper tile and the lower tile without collision between the two.

In another embodiment according to the present invention, in order to facilitate the access to the lower part of the upper tile, when maintenance is required, the lower fixation part 835 can further comprise at least one lifting bracket 1340 which protrudes away from the tile just enough to enable grabbing of the tile either with a tool or with the fingers. If the lifting bracket is to be used with a tool, it comprises an opening in which the tool may be inserted to facilitate the lifting of the tile.

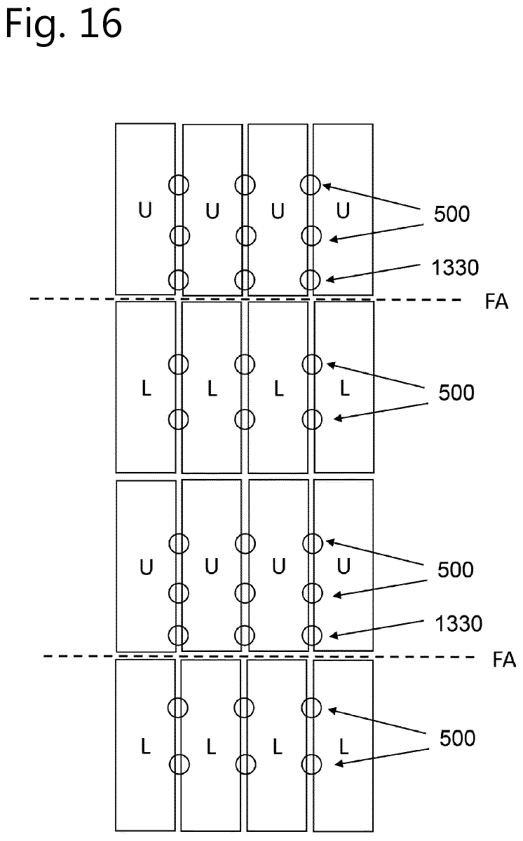

It is important to note that the fixation of a lower tile and upper tile works pair wise. Thus, in a tiled display comprising four by four tiles, there are eight pairs of upper U and lower L tiles, as shown in FIG. 16. The region of front access is indicated by the dashed line FA.

In another embodiment according to the present invention, an additional fastener is provided between un upper tile and a lower tile. Such a fastener can be placed at at least one location at the proximity of the joint edge of the upper and lower tile, said fastener being configured to be in a first locked position for the operation state and a second unlocked position for the maintenance state, wherein the change from the first to the second position and vice versa is activated from the front side.

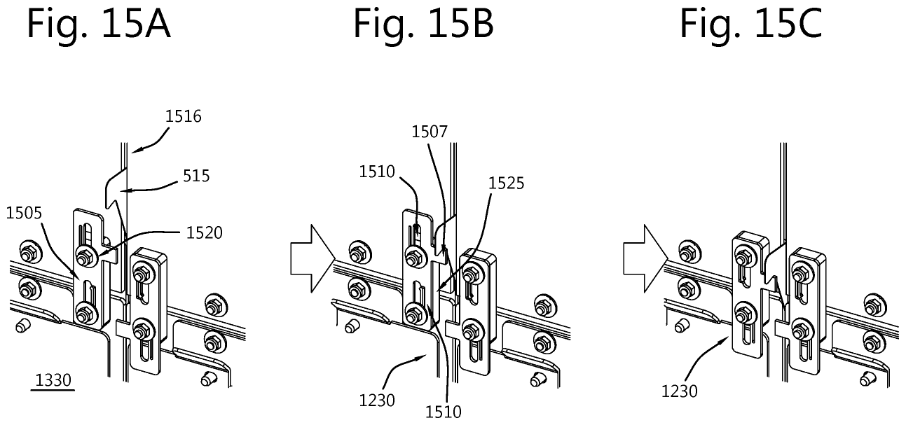

FIGS. 13 and 15 show an embodiment of such a fastener providing a vertical z-locking mechanism between an upper and a lower tile. The z-locking mechanism 1330 can be provided in the lower fixation part 835 of the upper tile, so as to lock the upper tile to the lower tile. This mechanism is a vertical z-locking mechanism. The steps required to activate this mechanism are shown in FIG. 15A to FIG. 15C. The activation of the mechanism is similar to the horizontal z-locking, i.e., with the use of a card-like tool 515 that is slid through the seam 1516.

FIG. 15A shows the vertical z-locking mechanism 1330 in the second unlocked-position for the maintenance state. The mechanism is preferably installed in at least one corner of the lower fixation part 835. The vertical z-locking mechanism 1330 comprises a sliding main body 1505 and a static second body 1525 placed between the sliding main body and the lower fixation part. The sliding main body further comprises at least one vertical groove 1510 preferably parallel to the seam between two neighboring tiles and is configured to receive a screw and a washer 1520 for improving the sliding the screw within the groove and distributing the load of the screw along the groove. The screw and washer are configured to be in a first locked position within the groove in the operation state and a second unlocked position within the groove in the maintenance state. In this embodiment, the higher position corresponds to the unlocked position and the lower position to the locked position. The screw further fixes the static second body to the lower fixation part. In order to activate the locking mechanism, the main body 1505 further comprises an arm 1507 extending from the main body towards the seam 1516 between two neighboring tiles, and wherein the arm 1507 acts as a lever arm upon application of a force at an extremity of the arm. The arm is long enough to cross the seam so as when a card-like tool 515 is inserted through the seam, the arm 1507 can act as a lever arm upon application of a force by the card-like tool at an extremity of the arm which is located at the seam, as illustrated on FIG. 15B. Preferably, the sliding main body has a rectangular shape having a length so as to have a surface of overlap with the corner 1230 (shown on FIGS. 12 and 15B) of the middle mounting bracket, so as to block the z-movement of the tiles at this location, when the vertical z-locking mechanism is in the locked position as shown in FIG. 15C. Note that the references have been indicated on the various FIGS. 15A, 15B and 15C for clarity.

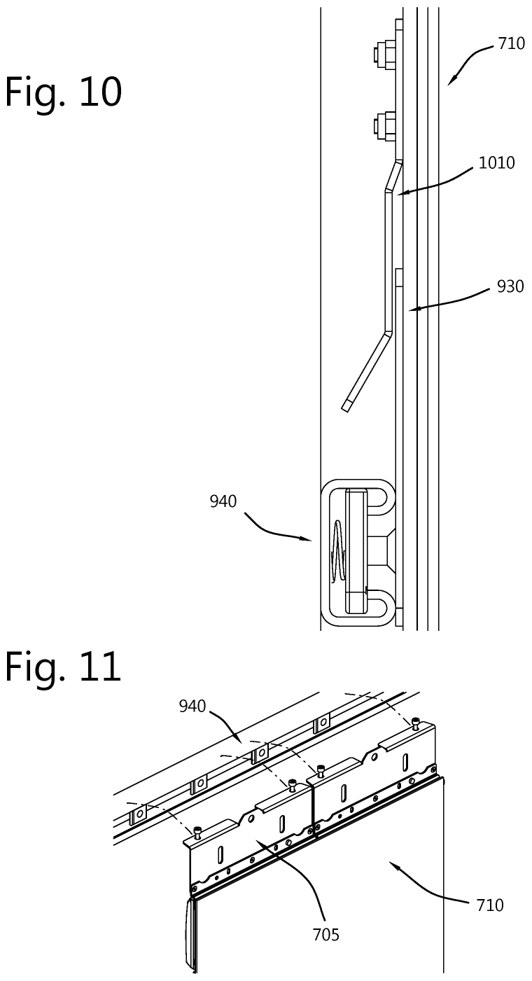

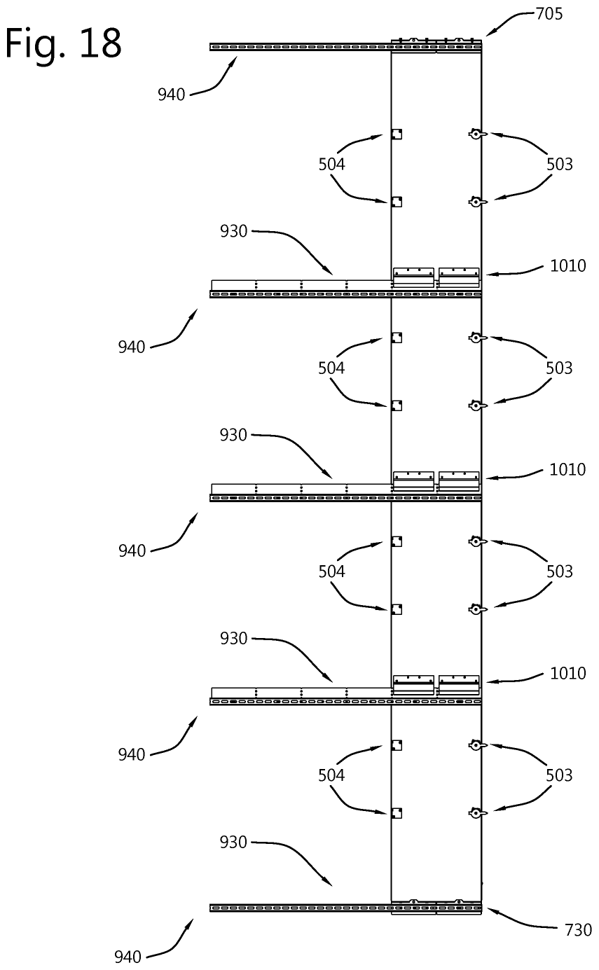

Additional mechanisms may be used to block the displacement in z, or the flexure of the individual tiles, so as to avoid visible seams but also to reduce vibrations of the tiles in the presence of wind. An example of such a mechanism is shown in FIG. 10 in combination with FIG. 9. FIG. 18 is a back view of FIG. 9. Preferably, additional horizontal z-profile bars 930 or steel plates fixed to trusses 940 are placed on the support structure at a plurality of locations of different heights (FIGS. 9 and 18) which correspond to positions of z-shaped brackets 1010 fixed at the back of the display tiles, as shown on FIG. 10, with nuts and bolts for example. The combination of the z-shaped brackets 1010 and the z-profile bars 930 enables to block or cancel the flexure of the display tiles at those locations. For installation, each z-shaped bracket 1010 can preferably be slipped into the corresponding z-profile bar 930.

However, in order to enable front access to a tile by means of bending as shown in FIG. 3, the position of the z-shaped brackets 1010 on the display tile has to satisfy certain conditions, depending on the size of the tile. The position of a z-shaped bracket 1010 has a similar effect as to reduce the length of the tile to the position of the bracket. Thus, the flexibility of the tile is also reduced and therefore the bending. In a preferred embodiment of the present invention, the z-shaped bracket is positioned in the range of a quarter of the length of a tile to a third of the length of the tile so as to enable bending of the tile in the remaining three quarter, two-third of the length of the tile. This is also shown in FIG. 3 wherein the z-shaped bracket 1010 is positioned in the upper part of the tile which is bended in the lower part for front access and maintenance. Thus, for an upper tile U as shown in FIG. 16, the position of the z-shaped bracket is in the upper part of the tile so as to enable the bending in the lower part, and for a lower tile L, the position of the z-shaped bracket is in the lower part of the tile so as to enable the bending in the upper part. However, in certain applications, the tiles may be longer, and therefore the z-shaped brackets may be installed at regular intervals along the back of the tile. For example, for a tile of 4.68 meters, a z-shaped bracket can be installed every 1.17 meters, and thus comprise three such brackets. This is illustrated on FIG. 18 and FIG. 9 which show three rows of z-shaped brackets installed at regular intervals in the back of the tiles. The bending of the tile is still possible given the 1.17 meters between the z-bracket and the lower or upper fixation part 705, or the middle mounting bracket 735 for a stacked tiled display, and given the flexural rigidity of the tile. Thus, the z-shaped mounting brackets may be placed anywhere at the back of a tile as long as the tiles may still be bent in the case of front access requirements.

FIG. 16 also shows possible positions for installing the horizontal z-locking mechanism 500 and the vertical z-locking mechanism 1330 described above. For example, each joint edge between two neighboring tiles is fixed at two locations by the horizontal z-locking mechanism 500, for example provided at a third and two thirds of the length of the tile. Only one or more horizontal z-locking mechanisms could be included. The vertical z-locking mechanism 1330 is preferably installed in the two lower corners of an upper tile, as shown in FIG. 16.

FIGS. 17A and 17B show two additional embodiments according to the present invention, in which the tiled display is curved. In the first embodiment of FIG. 17A, each individual tile is curved and the entire tiled display appears as a smooth curved display to the viewer. The bending of each individual tile is obtained by having a support structure with the desired curvature for the display. As each individual tile is flexible, when a tile is fixed to a curved support structure, it adopts the shape of the structure. However, as the tiles are usually rectangular, the bending is only achieved along the length of the tile. Along the width, the tile provides more resistance to the bending. Thus, in order to provide a curved display as the one shown on FIG. 17A, it is preferred to install the tiles horizontally and not vertically as in the previous embodiment.

In the embodiment of FIG. 17B, the entire display is curved but each individual tile keeps its flat shape. Thus, the resulting display is not a smooth curved display. The support structure of such a display is arranged in the desired shape. In this embodiment, the horizontal z-lock mechanism and the vertical z-lock mechanism are configured so as to still operate if two neighboring tiles are not in the same plane. Preferably, there is a tolerance within each z-lock mechanism which allows two neighboring tiles to be at an angle α of up to 20°, as shown in FIG. 17B. In the horizontal z-lock mechanism 500, this is achieved by providing a slit with a larger width so as to provide the required tolerance.

Note that other designs are possible for the tiled display, such as a cylindrical design for example or even a free form design.

In order to provide maintenance to a tile in a tiled display according to the present invention, some or all of the following steps can be performed, depending on which locking mechanism is used by the tiled display:
Unlocking the horizontal z-lock mechanism 500 with the card-like tool 515,
Unlocking the vertical z-lock mechanism 1330 with the card-like tool 515,
Lifting the upper tile away from the support by means of the at least one lifting brackets 1340,
Using a service rod, installed in openings 1250 and 1350, to prop the upper tile in a bent position,
if the upper tile is the malfunctioning tile, performing maintenance operations on the upper tile,
if the lower tile is the malfunctioning tile, lifting the lower tile away from a back structure such as a wall, and performing maintenance operations on the lower tile.

1-43. (canceled)

44. A tiled display comprising:
a plurality of display tiles, each display tile having a front side and a back side and at least a first and a second opposing edge and comprising addressable solid state light elements adapted to display at least a part of a static image or video frame on the front side;
a support structure for supporting the plurality of display tiles in an operation state and a maintenance state,
wherein in the operation state, each display tile has a first shape and wherein the first and second opposed edges of each of the plurality of display tiles are fixed to the support structure, and
in the maintenance state at least one of the plurality of display tiles is released from the support structure at at least the first edge and the at least one of the plurality of display tiles then having a second shape modified compared to said first shape and providing an opening between the first edge and the support structure.

45. The tiled display according to claim 44, wherein the display tiles have a third and fourth opposing edge not fixed to the support structure and wherein for a first and a second neighboring tile along the third edge of the first tile and the fourth edge of the second tile, the first and second tile are fixed together at at least one location along their third and fourth edges respectively by a fastener which is configured to be in a first locked position in an operation state and a second unlocked position in a maintenance state, wherein the change from the first locked position to the second unlocked position and vice versa being activated from the front side.

46. The tiled display according to claim 45, wherein the fastener is a locking mechanism comprising a first part configured to be attached to the back of the first tile and a second part configured to be attached to the back of the second tile, and when installed on the first and second tile, said first and second part being arranged so as to face each other and cooperate with one another so as to lock the relative position of the neighboring display tiles and in the z direction.

47. The tiled display according to claim 46, wherein
the first part of the locking mechanism comprises a rotating body configured to rotate around an axis, the axis being perpendicular to the display tile and an arm that extends away from the rotation axis, the arm and the rotating body forming a single solid body, and
the second part comprises a slit arranged so as to be perpendicular to the display tile and configured to receive the arm for fastening the two display tiles with respect to each other in the z direction.

48. The tiled display according to claim 47, wherein the slit is parallel to the seam between the two neighboring tiles.

49. The tiled display according to claim 47, wherein the width of the slit and the thickness of the arm are configured so that the first and the second tile fixed by locking mechanism form an angle of preferably at most 20 degrees at their joint edge so as to create a curved tiled display.

50. The tiled display according to claim 47, wherein the second part comprises a first part and a second part perpendicular to the first part, the first part and second part of the second part of the locking mechanism form a L-shape, the second part of the second part of the locking mechanism is parallel to the plane of the second display tile and is fastened to the second display tile.

51. The tiled display according to claim 45, wherein the first locked position of the locking mechanism is blocked by the cooperation between a clip having a resilient part and a rounded recess configured to receive a pin, the pin being perpendicular to the display tile and the clip being configured to keep the arm in the slit and maintain the first locked position.

52. The tiled display according to claim 51, wherein the clip rotates with the rotating body and the pin is fixed to the first part of the locking mechanism.

53. The tiled display according to claim 45, wherein the second unlocked position is blocked by the cooperation between a second clip having a resilient part and a rounded recess configured to receive a pin, the pin being perpendicular to the display tile and the clip being configured to maintain the mechanism unlocked.

54. The tiled display according to claim 53, wherein the second clip rotates with the rotating body and the pin is fixed to the first part of the locking mechanism.

55. The tiled display according to claim 44, further comprising a first upper tile and a second lower tile, the upper tile and the lower tile having a joint edge and wherein the lower part of the upper tile comprises a lower fixation part along its lower edge and the upper part of the lower tile comprises a middle mounting bracket along its upper edge and configured to cooperate with the lower fixation part so as to fix the upper tile and the lower tile together along their joint edge in the operation state.

56. The tiled display according to claim 55, wherein the lower fixation part and the middle mounting bracket further comprise alignment means for aligning the first upper tile to the second lower tile.

57. The tiled display according to claim 56, wherein the alignment means comprise at least one pin provided on the lower fixation part or on the mounting bracket and at least one opening provided on the mounting bracket or the lower fixation part, said pin and opening being configured to cooperate so as to align the upper tile and lower tile together in the operation state.

58. The tiled display according to claim 55, wherein the lower fixation part or the mounting bracket comprise at least one magnet for securing the fixation of the lower fixation part and the mounting bracket in the operation state.

59. The tiled display according to claim 58, wherein the part without magnets comprises for each magnet a cavity configured to receive the magnet so as to align the upper and lower tiles together in the operation state.

60. The tiled display according to claim 55, wherein at least one opening is provided on each of the mounting bracket and the lower fixation part for fixing a service rod for use so as to maintain one of the tiles in a bended position in the maintenance state.

61. The tiled display according to claim 55, wherein the lower fixation part further comprises a lifting bracket which protrudes away from the tile to enable grabbing of the tile with the fingers of a user or with a lifting tool, in which case the lifting bracket further comprises an opening configured to receive said lifting tool, for use in the maintenance state.

62. The tiled display according to claim 44, wherein an upper tile and a lower tile are configured to be locked together by an additional fastener at at least one location at the proximity of the joint edge of the upper and lower tile, said fastener being configured to be in a first locked position for the operation state and a second unlocked position for the maintenance state, wherein the change from the first to the second position and vice versa is activated from the front side.

63. The tiled display according to claim 62, wherein the fastener is a locking mechanism, said mechanism being installed on the lower fixation part of the upper tile and comprising a sliding main body and a static second body placed between the sliding main body and the lower fixation part, the sliding main body further comprises at least one vertical groove parallel to the seam between two neighboring tiles and is configured to receive a screw and a washer for sliding the screw within the groove, said screw and washer being configured to be in a first locked position within the groove in the operation state and a second unlocked position within the groove in the maintenance state, said screw further fixing the static second body to the lower fixation part, and wherein the main body further comprises an arm extending from the main body towards the seam between two neighboring tiles, and wherein the arm acts as a lever arm upon application of a force at an extremity of the arm, and wherein the sliding main body has a rectangular shape having a length so as to have a surface of overlap with a corner of the middle mounting bracket of the lower tile in the first locked position, so as to block a relative z-movement of the upper and lower tile at this location.

64. The tiled display according to claim 44, wherein each tile comprises at least one z-shaped bracket to be fixed at the back of a display tile, said at least one z-shaped bracket being configured to be inserted in a horizontal z-profile bar forming part of the support structure so as to reduce the flexure of the tile at the location of the z-shaped bracket.

65. The tiled display according to claim 44, wherein the tiles are bended so as to form a curved tiled display by providing a support structure with the required shape.

66. The tiled display according to claim 44, wherein the support structure is configured to provide each pair of neighboring tiles at an angle, said angle being of at most 20 degrees.

67. A horizontal locking mechanism for a tiled display for fixing a first and a second neighboring tile at at least one location along a joint edge, said tiles having a third and fourth opposing edge not fixed to the support structure and wherein for a first and a second neighboring tile along the third edge of the first tile and the fourth edge of the second tile, the first and second tiles are fixed together at at least one location along their third and fourth edges respectively by a fastener which is configured to be in a first locked position in an operation state and a second unlocked position in a maintenance state, wherein the change from the first locked position to the second unlocked position and vice versa being activated from the front side.

68. A vertical locking mechanism for fixing an upper tile and a lower tile at at least one location at the proximity of the joint edge of the upper and lower tile, said fastener being configured to be in a first locked position for the operation state and a second unlocked position for the maintenance state, wherein the change from the first to the second position and vice versa is activated from the front side.

69. A method of preparing a tiled display for maintenance, the tiled display comprising a plurality of display tiles, each display tile having a front side and a back side and at least a first and a second opposing edge and comprising addressable solid state light elements adapted to display at least a part of a static image or video frame on the front side, and a support structure for supporting the plurality of display tiles in an operation state and a maintenance state, the method comprising:
fixing at least one of the plurality of display tiles to the support structure in the operation state by fixing the first and second opposing edges to the support structure whereby the at least one of the plurality of display tiles has a first shape, and
placing at least one of the plurality of display tiles in the maintenance state by releasing at least the first edge of the at least one of the plurality of display tiles from the support structure, wherein the at least one of the plurality of display tiles has a second shape modified compared to said first shape and provides an opening between the first edge and the support structure.
